(19) United States
(12) Patent Application Publication
(10) Pub. No.: US 2012/0074398 A1
(43) Pub. Date: Mar. 29, 2012

(54) ORGANIC EL ILLUMINANT, ORGANIC EL ILLUMINATING DEVICE, AND METHOD FOR FABRICATING ORGANIC EL ILLUMINANT

(75) Inventor: Yoshimasa Fujita, Osaka (JP)

(73) Assignee: Sharp Kabushiki Kaisha, Osaka (JP)

(21) Appl. No.: 13/376,575

(22) PCT Filed: Mar. 11, 2010
(86) PCT No.: PCT/JP2010/001744

§ 371 Date: Dec. 6, 2011

(30) Foreign Application Priority Data
Jul. 1, 2009 (JP) 2009-157174

(51) Int. Cl. H01L 27/32; H01L 51/56; H01L 51/52

(52) U.S. Cl. 257/40; 438/42; 257/E51.019; 257/E51.018; 257/E27.119

(57) ABSTRACT

An organic EL illuminant (20) includes a first electrode (22), an organic EL layer (23), and a second electrode (24) which are sequentially stacked on a supporting base (21), wherein when a side in which the supporting base (21) is provided is one side, and a side in which the second electrode (24) is provided is the other side, a surface of the one side of at least one of the supporting base (21), the first electrode (22), or the second electrode (24) is larger than a surface of the other side of the at least one of the supporting base (21), the first electrode (22), or the second electrode (24).

### TECHNICAL FIELD

The present invention relates to organic electroluminescence (EL) illuminants, organic EL illuminating devices, and methods for fabricating organic EL illuminants.

### BACKGROUND ART

At present, as illuminating devices, white lamps and fluorescent lamps are widely used. As industrial illuminating devices, arc lamps, high-pressure mercury-vapor lamps, etc. are used. All these lamps use vacuum tubes as housings, and thus are inevitably limited in terms of their shapes.

In recent years, as illuminating devices whose shapes are not limited by their housings, there have been increasing demands for thin illuminating devices, and inorganic EL illuminating devices have been known as thin illuminating devices capable of emitting light of high brightness. However, the inorganic EL illuminating devices have problems such as a high drive voltage, low luminous efficiency, limited luminescent colors, etc. Thus, at the present time, it is difficult to put the inorganic EL illuminating devices into practical use.

On the other hand, organic EL illuminating devices have drawn attention as illuminating devices which can be reduced in thickness. The organic EL illuminating devices can be formed with organic EL illuminants formed on a flexible substrate, and thus have few limitations in terms of their shapes. Moreover, in terms of ease of dimming, brightness of emitted light, color rendering properties, an emission lifetime, luminous efficiency, etc., the organic EL illuminating devices are on a sufficient level of practical use.

Patent Document 1 describes an organic EL device formed on a flexible substrate. Moreover, Patent Document 2 describes that a light-emitting layer and a second electrode of an organic EL device are formed on a strip-shaped flexible substrate in a roll-to-roll process.

### CITATION LIST

### Patent Document

PATENT DOCUMENT 1: Japanese Patent Publication No. 2008-21575
PATENT DOCUMENT 2: International Patent Publication No. WO 2001/005194

### SUMMARY OF THE INVENTION

### Technical Problem

An organic EL illuminating device includes an organic EL illuminant formed by sequentially stacking a first electrode, an organic EL layer, and a second electrode on a supporting base. The thickness of the organic EL layer of the organic EL illuminant is very small, and is, for example, about 100 nm-200 nm. Here, when ITO which is a generally used material is used as the first electrode on the supporting base, the first electrode has a thickness of, for example, 100 nm-200 nm, and has a steep edge portion in terms of conductivity. In contrast, since the thickness of the organic EL layer is 100 nm-200 nm, the organic EL layer has a thickness significantly smaller than a preferable thickness at the edge portion of the first electrode due to a level difference at the edge portion of the first electrode. Therefore, at a peripheral portion of, in particular, a light-emitting area, the organic EL layer loses its function of insulating the first electrode from the second electrode, so that an electrical conduction path is established between the first electrode and the second electrode, causing leakage of a current, which causes poor emission at the light-emitting area. Thus, to prevent the leakage between the first electrode and the second electrode, an edge cover made of an insulating material is provided to cover a peripheral portion of the first electrode.

However, providing the edge cover has the following disadvantages. First, forming the edge cover by patterning complicates a fabrication process. Moreover, providing the edge cover increases cost of fabrication. In addition, even in the case of using a flexible substrate, the roll-to-roll process is no longer suitable to the formation of the organic EL layer and the second electrode because the edge cover is provided. Further, since moisture in an edge cover material causes degradation of an organic EL material, there are limitations of materials in terms of the fabrication process, that is, using a material whose moisture absorption rate is low, performing a vacuum bake process after forming the edge cover, etc. are required.

It is an objective of the present invention to provide an organic EL illuminant in which leakage of a current due to establishment of an electrical conduction path between a first electrode and a second electrode is reduced, and to easily fabricate the organic EL illuminant without forming an edge cover and without patterning. It is still another objective of the present invention to provide an organic EL illuminating device including an organic EL illuminant in which leakage of a current is reduced, where the organic EL illuminating device can emit light of high brightness for a long period of time.

### Solution to the Problem

An example organic EL illuminant of the present invention includes: a first electrode, an organic EL layer, and a second electrode which are sequentially stacked on a supporting base, wherein an orientation facing the supporting base is one side, and an orientation facing the second electrode is the other side, and a surface of the one side of at least one of the supporting base, the first electrode, or the second electrode is larger than a surface of the other side of the at least one of the supporting base, the first electrode, or the second electrode.

With the above configuration, a surface oat one side of at least one of the supporting base, the first electrode, or the second electrode is larger than a surface of the one side of the at least one of the supporting base, the first electrode, or the second electrode. Thus, also at a peripheral portion of a light-emitting area in which three layers, that is, the first electrode, the organic EL layer, and the second electrode, are stacked the organic EL layer has the function of insulating the first electrode from the second electrode. Thus, it is possible to reduce leakage of a current caused by a conduction path established between the first electrode and the second electrode.

Specifically, in the organic EL illuminant, at least one side surface of a layered product including the supporting base and the first electrode is an inclined plane which is outwardly inclined from the other side toward the one side, and the organic EL layer and the second electrode cover an area in which the supporting base and the first electrode are stacked, and the inclined plane of the layered product including the supporting base and the first electrode.

With the above configuration, at least one side surface of the layered product including the supporting base and the first electrode is an inclined plane which is outwardly inclined from the other side toward the one side. The organic EL layer and the second electrode cover an area in which the supporting base and the first electrode are stacked, and cover the inclined plane of the layered product including the supporting base and the first electrode The thickness of the organic EL layer between the first electrode and the second electrode is not significantly small even at a peripheral portion of the layered product, and the organic EL layer has the function of insulating the first electrode from the second electrode. Thus, it is possible to reduce leakage of a current caused by a conduction path established between the first electrode and the second electrode.

In this case, the inclined plane is preferably a flat surface.

With the above configuration, the side surface of the layered product is easily cut by a cutting blade, or the like, so that an inclined plane can be easily formed. Moreover, with the above configuration, the light emission area is large compared to the case where the layered product has a step-like side surface, and a high aperture ratio can be ensured. Furthermore, with the above configuration, most part of the organic EL layer is covered with the second electrode, and thus moisture entering the organic EL layer form the outside can be reduced by the second electrode. Thus, degradation of the organic EL layer by moisture can be alleviated.

In the example organic EL illuminant of the present invention, the organic EL illuminant is in the shape of a long-length body which linearly extends and has a constant width when viewed from above, and the side surface extending in a longitudinal direction of the layered product including the supporting base and the first electrode is the inclined plane.

With the above configuration, the organic EL illuminant is in the shape of a long-length body which linearly extends and has a constant width viewed from above. Thus, formation by using a roll-to-roll process can be easily possible.

In the example organic EL illuminant of the present invention, at least one side surface of a layered product including the supporting base, the first electrode, the organic EL layer, and the second electrode is an inclined plane which is outwardly inclined from the other side toward the one side.

With the above configuration, at least one surface of the layered product including the supporting base, the first electrode, the organic EL layer, and the second electrode is an inclined plane which is outwardly inclined from the other side toward the one side. Thus, an area of the first electrode which forms the inclined plane does not coincide with an area of the second electrode which forms the inclined plane when viewed from above. Therefore, in the light-emitting area in which three layers, that is, the first electrode, the organic EL layer, and the second electrode, are stacked, even when the organic EL layer has a small thickness at its peripheral portion, the organic EL layer has the function of insulating between both the electrodes at the peripheral portion. Thus, it is possible to reduce leakage of a current caused by a conduction path established between the first electrode and the second electrode.

In this case, the inclined plane is preferably a flat surface.

With the above configuration, the side surface of the layered product is cut by a cutting blade, or the like, so that it is possible to easily form an inclined plane. Moreover, with the above configuration, the light emission area is large compared to the case where t layered product has a step-like side surface. Thus, a high aperture ratio can be ensured. Furthermore, with the above configuration, most part of the organic EL layer is covered with the second electrode, moisture entering the organic EL layer from the outside can be reduced by the second electrode. Thus, degradation of the organic EL layer by moisture can be limited to a lesser extent.

In the example organic EL illuminant of the present invention, the organic EL illuminant is in the shape of a long-length body which linearly extends and has a constant width when viewed from above, a side surface extending in a longitudinal direction of the layered product including the supporting base, the first electrode, the organic EL layer, and the second electrode is the inclined plane.

With the above configuration, the organic EL illuminant is in the shape of a long-length body which linearly extend and has a constant width when viewed from above. Thus, formation by using a roll-to-roll process can be easily possible.

An example organic EL illuminating device of the present invention includes: multiple ones of the organic EL illuminant, wherein the plurality of organic EL illuminants each have a shape configured to be a long-length body which linearly extends and has a constant width when viewed from above, and the plurality of organic EL illuminants are electrically connected to each other in parallel.

An example method for fabricating the organic EL illuminant of the present invention includes: a first electrode formation process of forming the first electrode on the supporting base, an organic EL layer formation process of forming the organic EL layer on the first electrode, a second electrode formation process of forming the second electrode on the organic EL layer, and a cutting process of cutting a side surface of any one of the supporting base, the first electrode, the organic EL layer, or the second electrode such that the side surface is outwardly inclined from the other side toward the one side.

With the above method, when a simple cutting process is added, an organic EL illuminant in which leakage between the first electrode and the second electrode is reduced can be formed without forming an edge cover and without patterning.

In the above method, the cutting process is performed after the first electrode formation process and before the organic EL layer formation process.

In the above method, the cutting process is performed after the second electrode formation process.

In the above method, in the cutting process, the side surface is cut by a cutting blade.

With the above method, the side surface is easily cut by the cutting blade, so that a flat inclined plane can be formed.

### Advantages of the Invention

In the organic EL illuminant of the present invention, a surface at one side of at least one of the supporting base, the first electrode, or the second electrode is larger than a surface of the one side of the at least one of supporting base, the first electrode, or the second electrode, so that also at a peripheral portion of a light-emitting area in which three layers, that is, the first electrode, the organic EL layer, and the second electrode, are stacked, the organic EL layer has the function of insulating the first electrode from the second electrode. Thus, it is possible to reduce leakage of a current caused by a conduction path established between the first electrode and the second electrode. The organic EL illuminant can be easily formed without patterning, and without providing an edge cover. Moreover, an organic EL illuminating device including the organic EL illuminant is capable of emitting light of high brightness for a long period.

### BRIEF DESCRIPTION OF THE DRAWINGS

FIG. 1 is a plan view illustrating an organic EL illuminating device.

FIG. 2 is a cross-sectional view of the organic EL illuminating device taken along the line II-II of FIG. 1.

FIG. 3 is a cross-sectional view illustrating an organic EL illuminant of a first embodiment.

FIG. 4 is a cross-sectional view illustrating a conventional organic EL illuminant.

FIG. 5 is a cross-sectional view illustrating an organic EL illuminant of a second embodiment.

### DESCRIPTION OF EMBODIMENTS

### First Embodiment

### Organic EL Illuminating Device

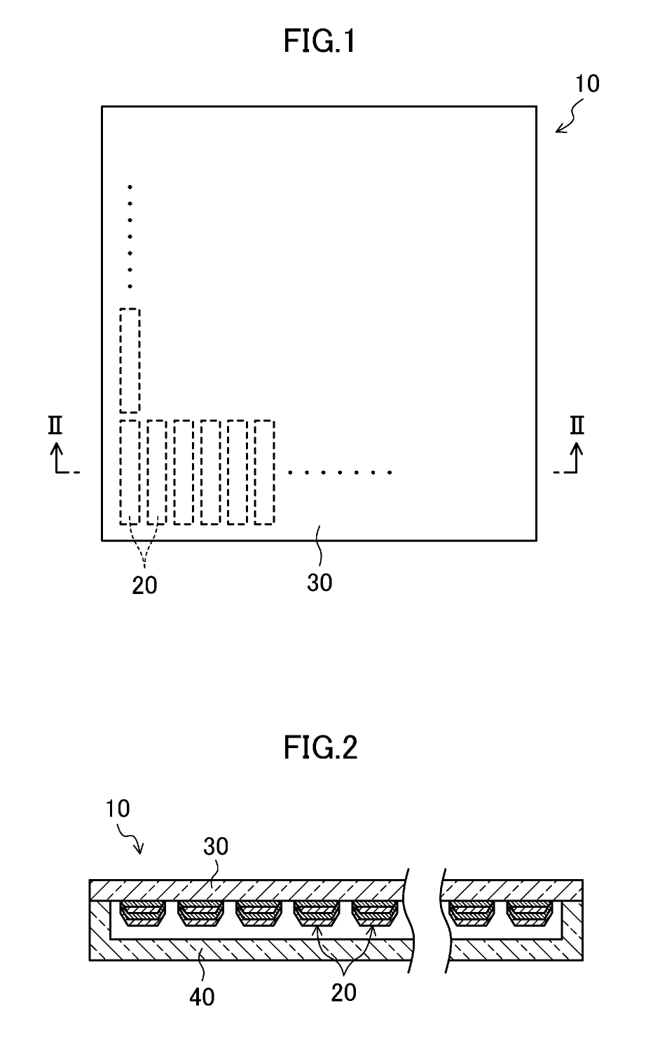

FIGS. 1, 2 illustrate an organic EL illuminating device 10 of a first embodiment. The organic EL illuminating device 10 is used as, for example, a room light or a backlight of a liquid crystal display device.

The organic EL illuminating device 10 includes a first substrate 30 and a second substrate 40 which are disposed to face each other, and a plurality of organic EL illuminants 20 sandwiched between the first substrate 30 and the second substrate 40.

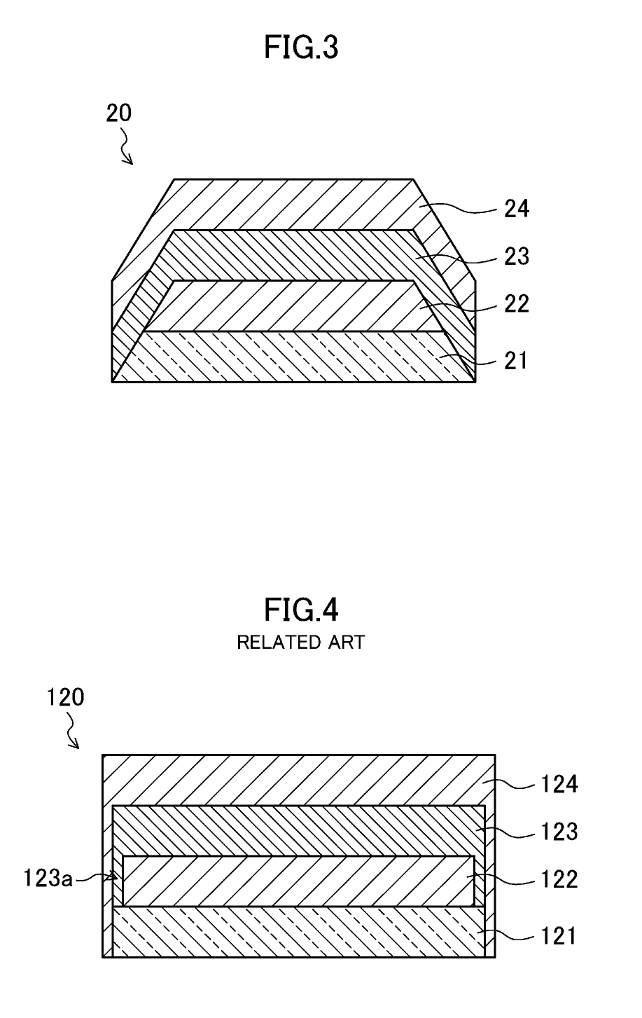

FIG. 3 is a cross-sectional view illustrating the organic EL illuminant 20. The organic EL illuminant 20 includes a first electrode 22, an organic EL layer 23, and a second electrode 24 which are stacked on a supporting base 21.

The supporting base 21 is made of, for example, a plastic film made of styrene resin, acrylic resin, polyethylene terephthalate resin (PET), polyethylene naphthalate resin (PEN), polybutylene terephthalate resin (PBT), or the like, or a metal thin film obtained by forming an insulating layer on a thin film made of aluminum, stainless steel, or the like.

As to the first electrode 22 and the second electrode 24, the first electrode 22 may be the anode and the second electrode 24 may be the cathode, or the first electrode 22 may be the cathode and the second electrode 24 may be the anode. Holes are injected from the anode into the organic EL layer 23, and electrons are injected from the cathode into the organic EL layer 23.

In order to enhance efficiency of hole injection into the organic EL layer 23, the anode is preferably made of a material having a high work function. Examples of the material having a high work function include metal such as Au, Ag, Pt, and Ni. Alternatively, when the organic EL illuminating device 10 has a structure in which emitted light is extracted through the anode (that is, a bottom emission type structure when the first electrode 22 is the anode, or a top emission type structure when the second electrode 24 is the anode), the anode is preferably, for example, a transparent electrode made of ITO, IDIXO, GZO, SnO2, or the like.

In order to enhance efficiency of electron injection into the organic EL layer 23, the cathode is preferably made of a material having a low work function. The cathode may be made of, for example, a layered product including metal having a low work function and stable metal, such as Ca/Al, Ce/Al, Cs/Al, or Ba/Al; an alloy such as a Ca:Al alloy, a Mg:Ag alloy, or a Li:Al alloy; or a layered product including an insulating thin film and a metal electrode, such as LiF/Al, LiF/Ca/Al, BaF₂/Ba/Al, or LiF/Al/Ag. In this case, when the thickness of the cathode is, for example, equal to or smaller than about 50 nm, it is possible to implement a structure in which emitted light is extracted through the cathode (that is, a bottom emission type structure when the first electrode 22 is the cathode, or a top emission type structure when the second electrode 24 is the cathode).

The organic EL layer 23 includes at least a light-emitting layer. The organic EL layer 23 may have a three-layer structure in which a hole-transport layer, the light-emitting layer, and an electron-transport layer are stacked. The organic EL layer 23 may have a five-layer structure in which a hole-injection layer, a hole-transport layer, the light-emitting layer, an electron-transport layer, and an electron-injection layer are stacked. The organic EL layer 23 may have a six-layer structure in which a hole-injection layer, a hole-transport layer, a hole-blocking layer, the light-emitting layer, an electron-blocking layer, and an electron-injection layer are stacked. The number of layers is not limited.

The hole-injection layer has the function of efficiently injecting holes received from the anode into the light-emitting layer. The HOMO level of a hole-injection material is preferably between the work function of the anode and the HOMO level of a light-emitting material.

The HOMO level of a hole-transport material of the hole-transport layer is preferably between the HOMO level of the hole-injection material and the HOMO level of the light-emitting material. Moreover, the LUMO level of the hole-transport material of the hole-transport layer is preferably lower than the LUMO level of the light-emitting material. Furthermore, a band gap between the hole-transport layer and the light-emitting layer is preferably large. When the HOMO level of the hole-transport material is between the HOMO level of the hole-injection material and the HOMO level of the light-emitting material, efficiency of hole transportation from the hole-injection layer to the light-emitting layer can be enhanced, and the drive voltage of the organic EL device can be limited to a low level. Moreover, when the LUMO level of the hole-transport material is lower than the LUMO level of the light-emitting material, leakage of electrons from the light-emitting layer into the hole-transport layer can be reduced, and the recombination rate of holes and electrons can be increased to enhance luminous efficiency. Furthermore, when the band gap between the hole-transport layer and the light-emitting layer is large, excitons can be confined in the light-emitting layer, and the luminous efficiency of the organic EL device can be enhanced.

As the hole-injection material and the hole-transport material, various low-molecular materials, various polymer materials, precursors of polymer materials, or the like may be used. Examples of the low-molecular material include an inorganic p-type semiconductor material, a porphyrin compound, aromatic tertiary amine compounds such as N,N′-bis-(3-methylphenyl)-N,N′-bis-(phenyl)-benzidine (TPD), and N,N′-di(naphthalene-1-yl)-N,N′-dephenyl-benzidine (NPD), a hydrazone compound, a quinacridone compound, a styrylamine compound, and the like. Examples of the polymer material include polyaniline (PANI), 3,4-polyethylene dioxythiophene/polystyrenesulfonate (PEDT/PSS), poly[triphenylamine derivative] (Poly-TPD), polyvinylcarbazole (PVCz), and the like. Examples of the precursor of polymer materials include a poly(p-phenylenevinylene) precursor (Pre-PPV), a poly(p-naphthalenevinylene) precursor (Pre-PNV), and the like. The hole-injection layer may be made of two or more of the hole-injection materials, and the hole-transport layer may be made of two or more of the hole-transport materials. The hole-injection layer and the hole-transport layer may include an additive such as a donor, an acceptor, etc.

The hole-injection layer and the hole-transport layer have, for example, a thickness of about 30 nm and a thickness of about 20 nm, respectively.

As an electron-blocking material of the electron-blocking layer, a material similar to that used as the hole-injection material may be used. Note that the absolute value of the LUMO level of the electron-blocking material is preferably smaller than the absolute value of the LUMO level of a material which has a smallest absolute value of the LUMO level in the light-emitting layer. This can enhance the effect of blocking electrons.

The hole-blocking layer has, for example, a thickness of about 10 nm

The light-emitting layer is made of a light-emitting material, examples of which include various low-molecular light-emitting materials, various polymer light-emitting materials, precursors of polymer light-emitting materials, and the like. Examples of the low-molecular light-emitting material include a aromatic dimethyldine compound such as 4,4′-bis(2,2′-diphenylvinyl)-biphenyl (DPVBi), an oxadiazole compound such as 5-methyl-2-[2-[4-(5-methyl-2-benzoxazolyl)phenyl]vinyl]benzoxazole, a triazole derivative such as 3-(4-biphenylyl)-4-phenyl-5-t-buthylphenyl-1,2,4-triazole (TAZ), a styryl benzene compound such as 1,4-bis(2-methylstyryl)benzene, fluorescent organic materials such as a tiopyrazine dioxide derivative, a benzoquinone derivative, a naphthoquinone derivative, an anthraquinone derivative, a diphenoquinone derivative, and a fluorenone derivative, fluorescent organic metal compounds such as an azomethine-zinc complex, and a (8-hydroxyquinolinato)aluminum complex (Alq3), and the like. Examples of the polymer light-emitting material include poly(2-decyloxy-1,4-phenylene) (DO-PPP), poly[2,5-bis-[2-(N,N,N-triethyl ammonium)ethoxy]-1,4-phenyl-alt-1,4-phenylene]dibromide (PPP-NEt3+), poly[2-(2′-ethylhexyloxy)-5-methoxy-1,4-phenylenevinylene] (MEH-PPV), poly[5-methoxy-(2-propanoxysulfonide)-1,4-phenylenevinylene] (MPS-PPV), poly[2,5-bis-(hexyloxy)-1,4-phenylene-(1-cyanovinylene)] (CN-PPV), poly(9,9-dioctylfluorene) (PDAF), polyspiro, and the like. Examples of the precursors of polymer light-emitting materials include a PPV precursor, a PNV precursor, a PPP precursor, and the like.

Note that the light-emitting layer may be made of two or more of the light-emitting materials. Moreover, a plurality of light-emitting layers may be stacked, and for example, a red-light-emitting layer including a red-light-emitting material, a green-light-emitting layer including a green-light-emitting material, and a blue-light-emitting layer including a blue-light-emitting material may be stacked to form light-emitting layers, so that it is possible to obtain emission of white light. The light-emitting layer may include a hole-transport material and an electron-transport material.

The light-emitting layer has, for example, a thickness of about 30 nm.

The LUMO level of the electron-transport material of the electron-transport layer is preferably between the LUMO level of an electron-injection material of the electron-injection layer and the LUMO level of the light-emitting material. Moreover, the HOMO level of the electron-transport material of the electron-transport layer is preferably higher than the HOMO level of the light-emitting material. Furthermore, a band gap between the electron-transport layer and the light-emitting layer is preferably large. When the LUMO level of the electron-transport material is between the LUMO level of the electron-injection material and the LUMO level of the light-emitting material, efficiency of electron transportation from the electron-injection layer to the light-emitting layer can be enhanced, and the drive voltage of the organic EL device can be limited to a low level. Moreover, when the HOMO level of the electron-transport material is lower than the HOMO level of the light-emitting material, leakage of holes from the light-emitting layer into the electron-transport layer can be reduced, and the luminous efficiency including recombination rate of holes and electrons can be enhanced. Furthermore, when the band gap between the electron-transport layer and the light-emitting layer is large, excitons can be confined in the light-emitting layer, and the luminous efficiency of the organic EL device can be improved.

As the electron-injection material of the electron-injection layer, a material having a higher LUMO level than the electron-transport material of the electron-transport layer is preferably used. This can enhance the efficiency of electron injection.

Moreover, as the electron-transport material of the electron-transport layer, a material having a higher electron mobility than the electron-injection material of the electron-injection layer is preferably used. This can enhance the efficiency of electron transportation from the electron-injection layer to the light-emitting layer.

Examples of the electron-injection material and the electron-transport material include an inorganic material serving as an n-type semiconductor, fluorenone derivatives such as a oxadiazole derivative, a triazole derivative, a tiopyrazine dioxide derivative, a benzoquinone derivative, a naphthoquinone derivative, an anthraquinone derivative, and a diphenoquinone derivative, a low-molecular material, polymer materials such as poly(oxadiazole) (Poly-OXZ), and polystyrene derivative (PSS), and the like.

In particular, examples of the electron-injection material include fluoride such as lithium fluoride (LiF) and barium fluoride (BaF₂), oxide such as lithium oxide (Li₂O), and the like.

The electron-transport layer and the electron-injection layer have, for example, a thickness of about 30 nm and a thickness of 1 nm, respectively.

Note that a protection film may be provided to cover the second electrode 24. With this configuration, moisture entering the organic EL layer 23 from the outside can be reduced.

Examples of a material for the protection film include a metal thin film made of, for example, Al or Ag, an organic film made of, for example, phthalocyanine, an inorganic film made of, for example, SiON, SiO, or SiN, and the like.

In the organic EL illuminant 20 configured as described above, a side surface in a length direction of a layered product including the supporting base 21 and the first electrode 22 is an inclined plane which is outwardly inclined from the first electrode 22 toward the supporting base 21. The organic EL illuminant 20 has a configuration in which the organic EL layer 23 is formed on the inclined plane, and a second electrode 24 is further provided on the organic EL layer 23.

The inclined plane may be a flat surface or a curved surface, but the inclined plane is preferably a flat surface because the flat surface is easily formed. When the inclined plane is a flat surface, the layered product including the supporting base 21 and the first electrode 22 of the organic EL illuminant 20 has a trapezoidal cross-section in a width direction thereof. When both side surfaces of the layered product are inclined planes, and the inclination angles of the inclined planes are equal to each other, the cross-section of the layered product is an isosceles trapezoid shape having a base angle of, for example, about 45°-60°.

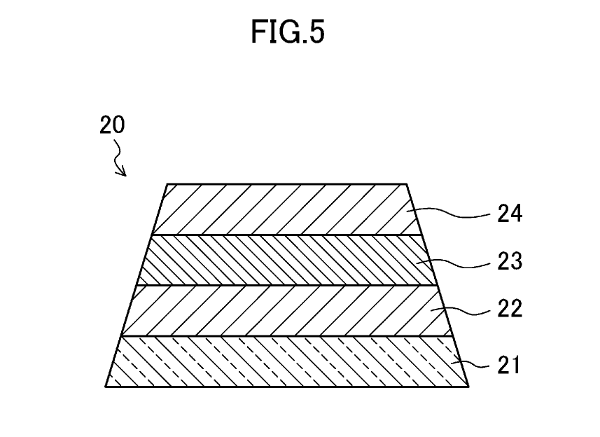

When a side surface of a layered product of an organic EL illuminant is not an inclined plane, the thickness of an organic EL layer 123a formed at the side surface is small as illustrated in FIG. 4, and an electrical conduction path may be established between a first electrode 122 and a second electrode 124, which may cause leakage. Moreover, in some cases, the organic EL layer may not be formed on the side surface of the layered product of the organic EL illuminant, and an electrical conduction path may be established between the first electrode 122 and the second electrode 124, which may cause leakage. Thus, an edge cover has to be provided on a peripheral portion of the first electrode 122 to prevent leakage between both the electrodes. However, since the side surface of the layered product of the organic EL illuminant 20 of the present embodiment is an inclined plane, the thickness of the organic EL layer 23 formed on the inclined plane is ensured. Therefore, even at a peripheral portion of the organic EL layer 23, the organic EL layer 23 has an insulation function between both the electrodes, and leakage caused due to establishment of an electrical conduction path between the first electrode 22 and the second electrode 24 can be reduced. Thus, providing an edge cover is not necessary, the fabrication process can be simplified, and the cost of fabricating the edge cover can be cut.

The organic EL illuminants 20 are disposed in space formed between the first substrate 30 and the second substrate 40, and are connected to an extraction terminal of the first substrate 30 so that the organic EL illuminants 20 are electrically connected to each other in parallel.

Each of the first substrate 30 and the second substrate 40 is, for example, a glass substrate or a resin substrate which is made of a transparent material. The first substrate 30 and the second substrate 40 may be flat plates, or may have a curved surface. Note that as long as any one of the first substrate 30 or the second substrate 40 is a transparent component, the other one of the first substrate 30 or the second substrate 40 may be opaque, and may be made of, for example, a metal component. The first substrate 30 and the second substrate 40 are disposed to face each other with the organic EL illuminants 20 being sandwiched therebetween, and are sealed with, for example, UV cured resin, thermosetting resin, or fritted glass so that the organic EL illuminants 20 are sealed. The space formed between the first substrate 30 and the second substrate 40 is adjusted to have an atmosphere of an inert gas such as nitrogen or argon, or a vacuum atmosphere. This can reduce damage by moisture or oxygen to the organic EL illuminant 20. In the space formed between the first substrate 30 and the second substrate 40, a moisture absorbent such as barium oxide may be provided.

The plurality of organic EL illuminants 20 are aligned in a width direction at an interval therebetween. The interval between the organic EL illuminants 20 is, for example, about 5 mm.

The anodes of the plurality of organic EL illuminants 20 may be connected to each other, or the cathodes of the plurality of organic EL illuminants 20 may be connected to each other. In any of these cases, an external power source can be simply connected to each organic EL illuminant 20.

In the organic EL illuminating device 10 having the above configuration, when a voltage is applied between the first electrode 22 and the second electrode 24, holes from the anode and electrons from the cathode are injected into the light-emitting layer, where one of the first electrode 22 or the second electrode 24 serves as the anode, and the other one of the first electrode 22 or the second electrode 24 serves as the cathode. Then, recombination of holes and electrons occurs in the light-emitting layer, and energy released due to the recombination excites the light-emitting material of the light-emitting layer. When the excited light-emitting material returns from an excited state to a ground state, fluorescence or phosphorescence is released. The fluorescence or the phosphorescence is emitted as light. In the organic EL illuminating device 10, poor emission due to leakage between the electrodes of the organic EL illuminant 20 is less likely to be caused, so that light of high brightness can be emitted for a long period.

<Method for Fabricating Organic EL Illuminating Device>

Next, a method for fabricating the organic EL illuminating device 10 will be described.

(Supporting Base Preparation Process)

First, a long-length film, which will be the supporting base 21 of the organic EL illuminant 20, is prepared. The film has, for example, a width of about 20 mm, and a length of about 10 m. The film is cut into, for example, 15-cm pieces in a length direction, so that each piece has the size of the organic EL illuminant 20.

(First Electrode Formation Process)

Next, by using a known process, for example, a dry process such as vapor-deposition, EB, MBE, or sputtering, or a wet process such as spin coating, printing, or ink-jet printing, the first electrode 22 is formed on the supporting base 21.

(Cutting Process)

Subsequently, side surfaces of the supporting base 21 provided with the first electrode are diagonally cut by a cutter so that the side surfaces in a length direction of a layered product including the supporting base 21 and the first electrode 22 are inclined planes. In this way, the supporting base 21 provided with the first electrode has a trapezoidal cross section.

After cutting the side surfaces, and after the formation of the first electrode 22, for example, ultrasonic cleaning using acetone or isopropyl alcohol for 10 minutes, and UV ozone cleaning for 30 minutes are performed to clean a surface of the electrode.

(Organic EL Layer Formation Process)

Next, to form the organic EL layer 23, the supporting base 21 provided with the first electrode is set in a roll-to-roll deposition device. The roll-to-roll deposition device includes a unit configured to form the layers included in the organic EL layer 23 and a unit configured to form the second electrode 24. The roll-to-roll deposition device is adjusted so that the entirety of the roll-to-roll deposition device is under a vacuum atmosphere, or an inert gas atmosphere.

The layers included in the organic EL layer 23 are formed by using a known method, for example, a dry process such as vacuum evaporation, or a wet process such as a doctor blade method, dip coating, a micro gravure method, spraying, ink-jet printing, or printing.

In forming the organic EL layer 23 by a wet process, coating liquid for forming organic layers is used, wherein the coating liquid is obtained by dissolving an organic material in a solvent. The coating liquid for forming the organic layers may contain two or more types of organic materials. The coating liquid for forming organic layers may contain bonding resin, a leveling agent, an additive such as a donor or an acceptor, or the like. Examples of the bonding resin include polycarbonate, polyester, and the like. As the solvent, any solvent may be used as long as an organic material can be dissolved or dispersed therein. Examples of the solvent include pure water, methanol, ethanol, THF, chloroform, xylene, trimethylbenzene, and the like.

Note that in forming the organic EL layer 23 by a wet process, the process is preferably performed under an inert gas atmosphere or a vacuum atmosphere in order to reduce damage to the organic material caused by moisture entering the organic EL layer 23. Moreover, in order to remove a remaining solvent, heating and drying are performed under a reduced pressure or an inert gas atmosphere.

(Second Electrode Formation Process)

Next, the second electrode 24 is formed by a known process, for example, a dry process such as vapor-deposition, EB, MBE, or sputtering, or a wet process such as spin coating, a printing method, or an ink jet method.

Subsequently, a protection film is formed by, for example, EB vapor-deposition, sputtering, ion plating, or resistor heating vapor-deposition.

A tape thus formed by the above processes is cut into pieces each having a predetermined length, thereby obtaining the organic EL illuminants 20.

Subsequently, the organic EL illuminants 20 are fixed on the first substrate 30 by a known transparent thermoset resin, or the like, and the extraction terminal provided to the first substrate 30 is electrically connected to the organic EL illuminants 20. Here, the organic EL illuminants 20 are arranged at an interval of about 1 mm-5 mm.

After fixing the organic EL illuminants 20 on the first substrate 30, the second substrate 40 is placed over the first substrate 30 to cover the organic EL illuminants 20, and is sealed with UV cured resin, or the like. Here, the sealing is performed under an atmosphere of an inert gas such as nitrogen or argon in a dry air booth or a glove box. The organic EL illuminating device 10 of the present embodiment can thus be formed.

According to the method for fabricating the organic EL illuminating device of the present embodiment, the first electrode 22, the organic EL layer 23, and the second electrode 24 can be easily formed without patterning.

### Second Embodiment

### Organic EL Illuminating Device

The structure of an organic EL illuminant 20 of an organic EL illuminating device 10 of a second embodiment is different from that of the first embodiment. The structure of the organic EL illuminant 20 will be described below. Note that the same reference numerals as those in the first embodiment are used to represent equivalent elements.

FIG. 5 is a cross-sectional view illustrating the organic EL illuminant 20 taken in a width direction. As in the first embodiment, the organic EL illuminant 20 includes a first electrode 22, an organic EL layer 23, and a second electrode 24 which are sequentially stacked on a supporting base 21.

In the organic EL illuminant 20, side surfaces in a length direction of a layered product including the supporting base 21, the first electrode 22, the organic EL layer 23, and the second electrode 24 are inclined planes which outwardly inclines from the second electrode 24 toward the supporting base 21.

Each inclined plane may be a flat surface, or may be a curved surface. However, the inclined plane is preferably a flat surface, because the flat surface can be easily formed. When the inclined plane is a flat surface, the layered product composed of the supporting base 21, the first electrode 22, the organic EL layer 23, and the second electrode 24 has a trapezoidal cross section in a width direction thereof. When both the side surfaces of the layered product are inclined planes, and their inclination angles are equal to each other, the cross section of the layered product is an isosceles trapezoid, and the base angle is, for example, about 45°-60°.

According to the present embodiment, the side surfaces of the layered product of the organic EL illuminant 20 are inclined planes, end portions of the first electrode 22 (areas forming the inclined planes) and end portions of the second electrode 24 (areas forming the inclined planes) are located on different lines when viewed from above. Thus, in a light-emitting area in which three layers, that is, the first electrode 22, the organic EL layer 23, and the second electrode 24, are stacked, the organic EL layer 23 has the function of insulating the electrodes from each other also at its peripheral portion, so that it is possible to reduce leakage caused by a conduction path established between both the electrodes.

<Method for Fabricating Organic EL Illuminating Device>

Next, a method for fabricating the organic EL illuminating device 10 of the second embodiment will be described. The method of the second embodiment is the same as that of the first embodiment except the process of fabricating the organic EL illuminant 20. The description of the same processes as those of the first example is omitted.

(Supporting Base Preparation Process, First Electrode Formation Process)

First, as in the first embodiment, the first electrode 22 is formed on the supporting base 21, and a surface of the supporting base 21 provided with the first electrode is subjected to ultrasonic cleaning and UV ozone cleaning.

(Organic EL Layer Formation Process, Second Electrode Formation Process)

Subsequently, the supporting base 21 provided with the first electrode is set in a roll-to-roll deposition device, and layers included in the organic EL layer 23 and the second electrode 24 are sequentially stacked.

(Cutting Process)

The supporting base 21 provided with the first electrode, the organic EL layer 23, and the second electrode 24 is removed from the roll-to-roll deposition device, and side surfaces in a length direction thereof is obliquely cut by a cutter, thereby forming inclined planes which are outwardly inclined from the second electrode 24 toward the supporting base 21. Here, the cutting is preferably performed so that the inclined planes are flat surfaces in terms of ease of process. After the cutting process, the supporting base 21 has a trapezoidal cross section.

Finally, a protection film covering the second electrode 24 is formed in a manner similar to that of the first embodiment. The organic EL illuminant 20 of the second embodiment can thus be formed.

Note that it has been described that the cross section of the organic EL illuminant 20 is trapezoidal, but in the cutting process, for example, of the side surfaces of the organic EL illuminant 20, only side surfaces corresponding to the first electrode 22, the organic EL layer 23, and the second electrode 24 may be cut to form the inclined planes. Also in this case, the end portions of the first electrode 22 and the second electrode 24 are located on different lines when viewed from above, and thus it is possible to reduce leakage at the end portions of the first electrode 22 and the second electrode 24.

### Test Evaluation

### First Example

According to the first embodiment, an organic EL illuminating device was fabricated.

First, a strip-shaped PET film having a width of 20 mm and a length of 10 m as a supporting base was used to fabricate an organic EL illuminant. On a surface of the PET film, an ITO film was formed as a first electrode. Side surfaces in a length direction of the PET film were cut by using a cutter so that the PET film had a trapezoidal cross section in a film width direction with a base angle of 60°. Then, the PET film provided with the ITO electrode was subjected to ultrasonic cleaning for 10 minutes, and UV-ozone cleaning for 30 minutes.

Next, the PET film provided with the ITO electrode was set in a roll-to-roll deposition device. Then, the PET film was passed through a roll at a constant speed of 1 msec, thereby forming layers included in the organic EL layers, the second electrode, and the protection film.

As the organic EL layer, first, a copper phthalocyanine (CuPc) film having a thickness of 30 nm as a hole-injection layer, a 4′-bis[N-(1-naphthyl)-N-phenyl-amino] biphenyl)(α-NPD) film having a thickness of 20 nm as a hole-transport layer, and a 4,4′-bis-1N,N′-(3-tolyl)amino-3,3′-dimethyl biphenyl (HMTPD) film having a thickness of 10 nm as a hole-blocking layer are sequentially formed. Next, codeposition of α-NPD (hole-transport material), TAZ (electron-transport material), and bis(2-(2′-benzol-[4,5-α]thienyl)pyridinato-N, C3′)iridium(acetylacetonate)(btp₂Ir(acac)) (red-light-emitting dopant) was performed while the deposition rates of these materials were controlled to be 0.6:1.4:0.15, thereby forming a red-light-emitting layer capable of transporting both holes and electrons and having a thickness of 20 nm On the red-light-emitting layer, a green-light-emitting layer capable of transporting both holes and electrons and having a thickness of 10 nm was formed by performing codeposition of α-NPD (hole-transport material), TAZ (electron-transport material), and Ir(ppy)₃ (green-light-emitting dopant) while the deposition rates of these materials are controlled to be 1.0:1.0:0.1. On the green-light-emitting layer, a blue-light-emitting layer capable of transporting both holes and electrons and having a thickness of 10 nm was formed by performing codeposition of α-NPD (hole-transport material), TAZ (electron-transport material), and 2-(4′-t-butylphenyl)-5-(4″-biphenylyl)-1,3,4-oxadiazole (t-Bu PBD) (blue-light-emitting dopant) while the deposition rates of these materials were controlled to be 1.5:0.5:0.2. In this way, a white-light-emitting layer was formed. Subsequently, on the white-light-emitting layer, a 2,9-dimethyl-4,7-diphenyl-1,10-phenanthroline (BCP) film having a thickness of 10 nm was formed as an electron-blocking layer, a tris(8-hydroxyquinoline)aluminum(Alq3) film having a thickness of 30 nm was formed as an electron-transport layer, and a lithium fluoride (LiF) film having a thickness of 1 nm was formed as an electron-injection layer.

Moreover, as a second electrode, an aluminum film having a thickness of 300 nm was formed on the organic EL layer. As a protection film, a SiON film having a thickness of 100 nm was formed on the second electrode.

The PET film on which the first electrode, the organic EL layer, the second electrode, and the protection film were formed as described above was wound around a roll, and then, cut into 15-cm pieces to form six organic EL illuminants, each of which was fixed to a glass substrate serving as a first substrate, and was electrically connected to an extraction terminal provided on the glass substrate. Here, the organic EL illuminants were electrically connected to each other in parallel.

Finally, to the first glass substrate, a second glass substrate serving as a sealing second substrate was fixed by UV cured resin. The sealing process was performed in a dry air booth.

When a voltage of 10 V was applied to the thus formed organic EL illuminating device, white-light emission of 5000 cd/m² was obtained.

### Second Example

An organic EL illuminating device of a second example was formed by the same method as that of the first example except that side surfaces in a length direction of a PET film were cut so that the PET film provided with a first electrode had a trapezoidal cross section in a width direction thereof with the base angle of 45°.

When a voltage of 10 V was applied to the organic EL illuminating device, white-light emission of 5000 cd/m² was obtained.

### Third Example

An organic EL illuminating device of the third example was formed by the same method as that of the first example except that a PEN film was used instead of the PET film.

When a voltage of 10 V was applied to the organic EL illuminating device, white-light emission of 5000 cd/m² was obtained.

### Fourth Example

An organic EL illuminating device was formed by the same method as that of the first example except that side surfaces in a length direction of a PET film provided with a first electrode were inclined planes which were outwardly inclined from the first electrode toward the film and were not flat. Each inclined plane had a shape as part of an outwardly expanding arc in a cross section in a width direction of the PET film provided with the first electrode.

When a voltage of 10 V was applied to the organic EL illuminating device, white-light emission of 5000 cd/m² was obtained.

### Fifth Example

An organic EL illuminating device was formed according to the method for fabricating of the second embodiment.

A PET film provided with a first electrode having a rectangular cross section in a width direction thereof was set in a roll-to-roll deposition device to form an organic EL layer and a second electrode. Then, side surfaces in a length direction of the PET film were cut so that a trapezoidal cross section with a base angle of 45° was obtained, and a protection film was further formed.

Note that details of the method for forming films were the same as those of the first example.

When a voltage of 10 V was applied to the organic EL illuminating device, white-light emission of 5000 cd/m² was obtained.

### INDUSTRIAL APPLICABILITY

The present invention is useful to organic EL illuminants, organic EL illuminating devices, and methods for fabricating organic EL illuminants.

### DESCRIPTION OF REFERENCE CHARACTERS

10 Organic EL Illuminating Device
20 Organic EL Illuminant
21 Supporting base
22 First Electrode
23 Organic EL Layer
24 Second Electrode
30 First Substrate
40 Second Substrate

1. An organic EL illuminant comprising:
a first electrode,
an organic EL layer, and
a second electrode which are sequentially stacked on a supporting base, wherein
an orientation facing the supporting base is one side, and an orientation facing the second electrode is the other side, and
a surface of the one side of at least one of the supporting base, the first electrode, or the second electrode is larger than a surface of the other side of the at least one of the supporting base, the first electrode, or the second electrode.

2. The organic EL illuminant of claim 1, wherein
at least one side surface of a layered product including the supporting base and the first electrode is an inclined plane which is outwardly inclined from the other side toward the one side, and
the organic EL layer and the second electrode cover an area in which the supporting base and the first electrode are stacked, and cover the inclined plane of the layered product including the supporting base and the first electrode.

3. The organic EL illuminant of claim 2, wherein
the inclined plane is a flat surface.

4. The organic EL illuminant of claim 3, wherein
the organic EL illuminant is in the shape of a long-length body which linearly extends and has a constant width when viewed from above, and
the side surface extending in a longitudinal direction of the layered product including the supporting base and the first electrode is the inclined plane.

5. The organic EL illuminant of claim 1, wherein
at least one side surface of a layered product including the supporting base, the first electrode, the organic EL layer, and the second electrode is an inclined plane which is outwardly inclined from the other side toward the one side.

6. The organic EL illuminant of claim 5, wherein
the inclined plane is a flat surface.

7. The organic EL illuminant of claim 4, wherein
the organic EL illuminant is in the shape of a long-length body which linearly extends and has a constant width when viewed from above,
a side surface extending in a longitudinal direction of the layered product including the supporting base, the first electrode, the organic EL layer, and the second electrode is the inclined plane.

8. An organic EL illuminating device comprising:
multiple ones of the organic EL illuminant of claim 1, wherein
the plurality of organic EL illuminants each have a shape configured to be a long-length body which linearly extends and has a constant width when viewed from above, and
the plurality of organic EL illuminants are electrically connected to each other in parallel.

9. A method for fabricating the organic EL illuminant of claim 1, comprising
a first electrode formation process of forming the first electrode on the supporting base,
an organic EL layer formation process of forming the organic EL layer on the first electrode,
a second electrode formation process of forming the second electrode on the organic EL layer, and
a cutting process of cutting a side surface of any one of the supporting base, the first electrode, the organic EL layer, or the second electrode so that the side surface is outwardly inclined from the other side toward the one side.

10. The method of claim 9, wherein
the cutting process is performed after the first electrode formation process and before the organic EL layer formation process.

11. The method of claim 9, wherein
the cutting process is performed after the second electrode formation process.

12. The method of any one of claim 9, wherein
in the cutting process, the side surface is cut by a cutting blade.
